(19) United States
(12) Patent Application Publication
(10) Pub. No.: US 2025/0309842 A1
(43) Pub. Date: Oct. 2, 2025

(54) RADIO FREQUENCY AMPLIFIER WITH INCREASED INPUT IMPEDANCE

(71) Applicant: Skyworks Solutions, Inc., Irvine, CA (US)

(72) Inventors: Junhyung Lee, Irvine, CA (US); Hang Zhao, Irvine, CA (US); Johannes Jacobus Emile Maria Hageraats, Kamuela, HI (US); Aravind Kumar Padyana, Irvine, CA (US)

(21) Appl. No.: 19/096,697

(22) Filed: Mar. 31, 2025

Related U.S. Application Data
(60) Provisional application No. 63/572,611, filed on Apr. 1, 2024.

(51) Int. Cl. H03F 3/24; H04B 1/04

(52) U.S. Cl. CPC H03F 3/245; H03F 2200/451; H04B 1/0458

(57) ABSTRACT

A cascode amplifier including a first field-effect transistor with a gate coupled to a first radio frequency input, and a second field-effect transistor disposed between the first field-effect transistor and a radio frequency output. A source of the second field-effect transistor connected to a drain of the first field-effect transistor. A first neutralization circuit has a first tunable capacitor and is connected at one end to a drain of the first field-effect transistor. A feedback circuit includes a first tunable resistor and is connected in series between the supply node and the first radio frequency input. The first tunable capacitor and the first tunable resistor are controllable to increase an input impedance of the radio frequency amplifier.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to amplifiers for use in radio frequency (RF) electronics.

### Description of the Related Technology

Radio frequency amplifiers can be used to amplify signals in radio frequency systems. For example, a low noise amplifier (LNA) can be used to boost the amplitude of a relatively weak radio frequency (RF) signal received via an antenna. Thereafter, the boosted RF signal can be used for a variety of purposes, including, for example, driving a switch, a mixer, and/or a filter in an RF communication system.

Examples of RF communication systems with one or more LNAs include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard. LNAs can be included in RF communication systems to amplify signals of a wide range of frequencies. For example, an LNA can be used to provide low noise amplification to RF signals in a frequency range of about 30 kHz to 300 GHz, such as in the range of about 450 MHz to about 6 GHz for certain communications standards.

### SUMMARY

In some aspects, the techniques described herein relate to a radio frequency amplifier including: a cascode amplifier configured to receive an operating power via a supply node and amplify a radio frequency signal, the cascode amplifier including a first field-effect transistor with a gate coupled to a first radio frequency input, and a second field-effect transistor disposed between the first field-effect transistor and a radio frequency output, a source of the second field-effect transistor connected to a drain of the first field-effect transistor; a first neutralization circuit including a first tunable capacitor and connected at one end to a drain of the first field-effect transistor; and a feedback circuit including a first tunable resistor and connected in series between the supply node and the first radio frequency input, the first tunable capacitor and the first tunable resistor controllable to increase an input impedance of the radio frequency amplifier.

In some aspects, the techniques described herein relate to a radio frequency amplifier further including a third field-effect transistor with a gate coupled to a second radio frequency input, and the source of the second field-effect transistor connected to a drain of the third field-effect transistor, and the feedback circuit further including a second tunable resistor connected in series between the supply node and the second radio frequency input.

In some aspects, the techniques described herein relate to a radio frequency amplifier wherein the first radio frequency input corresponds to a first receive frequency band and the second radio frequency input corresponds to a second receive frequency band.

In some aspects, the techniques described herein relate to a radio frequency amplifier further including a second neutralization circuit including a second tunable capacitor, the second neutralization circuit disposed between a drain and a source of the second field-effect transistor.

In some aspects, the techniques described herein relate to a radio frequency amplifier wherein the feedback circuit includes a capacitor and the first tunable resistor connected in series.

In some aspects, the techniques described herein relate to a radio frequency amplifier wherein another end of the first neutralization circuit is connected to a source of the first field-effect transistor.

In some aspects, the techniques described herein relate to a radio frequency amplifier wherein another end of the first neutralization circuit is connected to a ground.

In some aspects, the techniques described herein relate to a radio frequency module including: a packaging substrate configured to receive a plurality of components; and a radio frequency amplifier including a cascode amplifier configured to receive an operating power via a supply node and amplify a radio frequency signal, the cascode amplifier including a first field-effect transistor with a gate coupled to a first radio frequency input, and a second field-effect transistor disposed between the first field-effect transistor and a radio frequency output, a source of the second field-effect transistor connected to a drain of the first field-effect transistor; and a first neutralization circuit including a first tunable capacitor, the first neutralization circuit connected at one end to a drain of the first field-effect transistor; and a feedback circuit including a first tunable resistor and connected in series between the supply node and the first radio frequency input, the first tunable capacitor and the first tunable resistor controllable to increase an input impedance of the radio frequency amplifier.

In some aspects, the techniques described herein relate to a radio frequency module wherein the radio frequency module is a front-end module.

In some aspects, the techniques described herein relate to a radio frequency module wherein another end of the first neutralization circuit is connected to a source of the first field-effect transistor.

In some aspects, the techniques described herein relate to a radio frequency module wherein another end of the first neutralization circuit is connected to a ground.

In some aspects, the techniques described herein relate to a radio frequency module further including a second neutralization circuit including a second tunable capacitor, the second neutralization circuit disposed between a drain and a source of the second field-effect transistor.

In some aspects, the techniques described herein relate to a radio frequency module further including a third field-effect transistor with a gate coupled to a second radio frequency input, and the source of the second field-effect transistor connected to a drain of the third field-effect transistor, and the feedback circuit further including a second tunable resistor connected in series between the supply node and the second radio frequency input.

In some aspects, the techniques described herein relate to a radio frequency module wherein the first radio frequency input corresponds to a first receive frequency band and the second radio frequency input corresponds to a second receive frequency band.

In some aspects, the techniques described herein relate to a mobile device including: a transceiver configured to generate a radio frequency signal; and a radio frequency module including a cascode amplifier configured to receive an operating power via a supply node and amplify a radio frequency signal, the cascode amplifier including a first field-effect transistor with a gate coupled to a first radio frequency input, and a second field-effect transistor disposed between the first field-effect transistor and a radio frequency output, a source of the second field-effect transistor connected to a drain of the first field-effect transistor; and a first neutralization circuit including a first tunable capacitor, the first neutralization circuit connected at one end to a drain of the first field-effect transistor; and a feedback circuit including a first tunable resistor and connected in series between the supply node and the first radio frequency input, the first tunable capacitor and the first tunable resistor controllable to increase an input impedance of the cascode amplifier.

In some aspects, the techniques described herein relate to a mobile device wherein another end of the first neutralization circuit is connected to a source of the first field-effect transistor.

In some aspects, the techniques described herein relate to a mobile device wherein another end of the first neutralization circuit is connected to a ground.

In some aspects, the techniques described herein relate to a mobile device further including a second neutralization circuit including a second tunable capacitor, the second neutralization circuit disposed between a drain and a source of the second field-effect transistor.

In some aspects, the techniques described herein relate to a mobile device further including a third field-effect transistor with a gate coupled to a second radio frequency input, and the source of the second field-effect transistor connected to a drain of the third field-effect transistor, and the feedback circuit further including a second tunable resistor connected in series between the supply node and the second radio frequency input.

In some aspects, the techniques described herein relate to a mobile device wherein the first radio frequency input corresponds to a first receive frequency band and the second radio frequency input corresponds to a second receive frequency band.

In some aspects, the techniques described herein relate to a radio frequency amplifier including: a cascode amplifier configured to receive an operating power via a supply node and amplify a radio frequency signal, the cascode amplifier including a first field-effect transistor with a gate coupled to a first radio frequency input corresponding to a first receive band, a second field-effect transistor with a gate coupled to a second radio frequency input corresponding to a second receive band, and a third field-effect transistor, a source of the third field-effect transistor connected to a drain of the first field-effect transistor and to a drain of the second field-effect transistor; and a first tunable resistor connected in series between the supply node and the first radio frequency input and further including a second tunable resistor connected between the supply node and the second radio frequency input, the first and second tunable resistors controllable to increase an input impedance of the radio frequency amplifier.

In some aspects, the techniques described herein relate to a radio frequency amplifier further including a first neutralization circuit including a first tunable capacitor and connected at one end to a drain of the first field-effect transistor.

In some aspects, the techniques described herein relate to a radio frequency amplifier further including a second neutralization circuit including a second tunable capacitor, the second neutralization circuit disposed between a drain and a source of the second field-effect transistor.

In some aspects, the techniques described herein relate to a radio frequency amplifier wherein another end of the first neutralization circuit is connected to a source of the first field-effect transistor.

In some aspects, the techniques described herein relate to a radio frequency amplifier wherein another end of the first neutralization circuit is connected to a ground.

In some aspects, the techniques described herein relate to a radio frequency amplifier further including a capacitor connected in series with the first tunable resistor.

In some aspects, the techniques described herein relate to a radio frequency module including: a packaging substrate configured to receive a plurality of components; and a cascode amplifier arranged on the packaging substrate and configured to receive an operating power via a supply node and amplify a radio frequency signal, the cascode amplifier including a first field-effect transistor with a gate coupled to a first radio frequency input corresponding to a first receive band, a second field-effect transistor with a gate coupled to a second radio frequency input corresponding to a second receive band, and a third field-effect transistor, a source of the third field-effect transistor connected to a drain of the first field-effect transistor and to a drain of the second field-effect transistor, the cascode amplifier further including a first tunable resistor connected in series between the supply node and the first radio frequency input and further including a second tunable resistor connected between the supply node and the second radio frequency input, the first and second tunable resistors controllable to increase an input impedance of the radio frequency amplifier.

In some aspects, the techniques described herein relate to a radio frequency module further including a first neutralization circuit including a first tunable capacitor and connected at one end to a drain of the first field-effect transistor.

In some aspects, the techniques described herein relate to a radio frequency module further including a second neutralization circuit including a second tunable capacitor, the second neutralization circuit disposed between a drain and a source of the second field-effect transistor.

In some aspects, the techniques described herein relate to a radio frequency module wherein another end of the first neutralization circuit is connected to a source of the first field-effect transistor.

In some aspects, the techniques described herein relate to a radio frequency module wherein another end of the first neutralization circuit is connected to a ground.

In some aspects, the techniques described herein relate to a radio frequency module further including a capacitor connected in series with the first tunable resistor.

In some aspects, the techniques described herein relate to a mobile device including: a transceiver configured to generate a radio frequency signal; and a radio frequency module including a cascode amplifier configured to receive an operating power via a supply node and amplify a radio frequency signal, the cascode amplifier including a first field-effect transistor with a gate coupled to a first radio frequency input corresponding to a first receive band, a second field-effect transistor with a gate coupled to a second radio frequency input corresponding to a second receive band, and a third field-effect transistor, a source of the third field-effect transistor connected to a drain of the first field-effect transistor and to a drain of the second field-effect transistor, the cascode amplifier further including a first tunable resistor connected in series between the supply node and the first radio frequency input and further including a second tunable resistor connected between the supply node and the second radio frequency input, the first and second tunable resistors controllable to increase an input impedance of the cascode amplifier.

In some aspects, the techniques described herein relate to a mobile device further including a first neutralization circuit including a first tunable capacitor and connected at one end to a drain of the first field-effect transistor.

In some aspects, the techniques described herein relate to a mobile device further including a second neutralization circuit including a second tunable capacitor, the second neutralization circuit disposed between a drain and a source of the second field-effect transistor.

In some aspects, the techniques described herein relate to a mobile device wherein another end of the first neutralization circuit is connected to a source of the first field-effect transistor.

In some aspects, the techniques described herein relate to a mobile device wherein another end of the first neutralization circuit is connected to a ground.

In some aspects, the techniques described herein relate to a mobile device further including a capacitor connected in series with the first tunable resistor.

In some aspects, the techniques described herein relate to a low-noise amplifier including: an input node configured to receive a radio-frequency signal; an output node configured to output an amplified radio-frequency signal; a cascode amplifying stage configured to receive an operating power via a supply node and amplify the radio-frequency signal, the cascode amplifying stage including a first field-effect transistor with a gate coupled to the input node, and a second field-effect transistor disposed between the first field-effect transistor and the output node; and a feedback circuit connecting the supply node to the input node in order to increase an input impedance of the low-noise amplifier.

In some aspects, the techniques described herein relate to a low-noise amplifier wherein the feedback circuit includes a capacitor and a resistor connected in series.

In some aspects, the techniques described herein relate to a low-noise amplifier further including a first neutralization circuit with one end connected to a cascode node between the first field-effect transistor and the second field-effect transistor.

In some aspects, the techniques described herein relate to a low-noise amplifier wherein the first neutralization circuit includes an adjustable capacitor.

In some aspects, the techniques described herein relate to a low-noise amplifier wherein another end of the first neutralization circuit is connected to a source of the first field-effect transistor.

In some aspects, the techniques described herein relate to a low-noise amplifier wherein another end of the first neutralization circuit is connected to a ground.

In some aspects, the techniques described herein relate to a low-noise amplifier further including a second neutralization circuit disposed between a drain and a source of the second field-effect transistor.

In some aspects, the techniques described herein relate to a low-noise amplifier wherein the second neutralization circuit includes an adjustable capacitor.

In some aspects, the techniques described herein relate to a low-noise amplifier including: an input node configured to receive a radio-frequency signal; an output node configured to output an amplified radio-frequency signal; a cascode amplifying stage configured to receive an operating power via a supply node and amplify the radio-frequency signal, the cascode amplifying stage including a first field-effect transistor with a gate coupled to the input node, and a second field-effect transistor disposed between the first field-effect transistor and the output node; and a first neutralization circuit with one end connected to a cascode node between the first field-effect transistor and the second field-effect transistor in order to increase an input impedance of the low-noise amplifier.

In some aspects, the techniques described herein relate to a low-noise amplifier wherein the first neutralization circuit includes an adjustable capacitor.

In some aspects, the techniques described herein relate to a low-noise amplifier wherein another end of the first neutralization circuit is connected to a source of the first field-effect transistor.

In some aspects, the techniques described herein relate to a low-noise amplifier wherein another end of the first neutralization circuit is connected to a ground.

In some aspects, the techniques described herein relate to a low-noise amplifier further including a feedback circuit connecting the supply node to the input node.

In some aspects, the techniques described herein relate to a low-noise amplifier wherein the feedback circuit includes a capacitor and a resistor connected in series.

In some aspects, the techniques described herein relate to a low-noise amplifier further including a second neutralization circuit disposed between a drain and a source of the second field-effect transistor.

In some aspects, the techniques described herein relate to a low-noise amplifier wherein the second neutralization circuit includes an adjustable capacitor.

In some aspects, the techniques described herein relate to a radio-frequency module including: a packaging substrate configured to receive a plurality of components; a low-noise amplifier implemented on the packaging substrate, the low-noise amplifier including an input node configured to receive an radio-frequency signal, an output node configured to output an amplified radio-frequency signal, a cascode amplifying stage configured to receive an operating power via a supply node and amplify the radio-frequency signal, the cascode amplifying stage including a first field-effect transistor with a gate coupled to the input node, and a second field-effect transistor disposed between the first field-effect transistor and the output node, and a feedback circuit connecting the supply node to the input node in order to increase an input impedance of the low-noise amplifier.

In some aspects, the techniques described herein relate to a radio-frequency module wherein the radio-frequency module is a front-end module.

In some aspects, the techniques described herein relate to a radio-frequency module wherein the feedback circuit includes a capacitor and a resistor connected in series.

In some aspects, the techniques described herein relate to a radio-frequency module wherein the low-noise amplifier further includes a first neutralization circuit with one end connected to a cascode node between the first field-effect transistor and the second field-effect transistor.

In some aspects, the techniques described herein relate to a radio-frequency module wherein the first neutralization circuit includes an adjustable capacitor.

In some aspects, the techniques described herein relate to a radio-frequency module wherein another end of the first neutralization circuit is connected to a source of the first field-effect transistor.

In some aspects, the techniques described herein relate to a radio-frequency module wherein another end of the first neutralization circuit is connected to a ground.

In some aspects, the techniques described herein relate to a radio-frequency module wherein the low-noise amplifier further includes a second neutralization circuit disposed between a drain and a source of the second field-effect transistor.

In some aspects, the techniques described herein relate to a radio-frequency module wherein the second neutralization circuit includes an adjustable capacitor.

In some aspects, the techniques described herein relate to a radio-frequency module including: a packaging substrate configured to receive a plurality of components; a low-noise amplifier implemented on the packaging substrate, the low-noise amplifier including an input node configured to receive an radio-frequency signal, an output node configured to output an amplified radio-frequency signal, a cascode amplifying stage configured to receive an operating power via a supply node and amplify the radio-frequency signal, the cascode amplifying stage including a first field-effect transistor with a gate coupled to the input node, and a second field-effect transistor disposed between the first field-effect transistor and the output node; and a first neutralization circuit with one end connected to a cascode node between the first field-effect transistor and the second field-effect transistor in order to increase an input impedance of the low-noise amplifier.

In some aspects, the techniques described herein relate to a radio-frequency module wherein the radio-frequency module is a front-end module.

In some aspects, the techniques described herein relate to a radio-frequency module wherein the first neutralization circuit includes an adjustable capacitor.

In some aspects, the techniques described herein relate to a radio-frequency module wherein another end of the first neutralization circuit is connected to a source of the first field-effect transistor.

In some aspects, the techniques described herein relate to a radio-frequency module wherein another end of the first neutralization circuit is connected to a ground.

In some aspects, the techniques described herein relate to a radio-frequency module wherein the low-noise amplifier further includes a feedback circuit connecting the supply node to the input node.

In some aspects, the techniques described herein relate to a radio-frequency module wherein the feedback circuit includes a capacitor and a resistor connected in series.

In some aspects, the techniques described herein relate to a radio-frequency module wherein the low-noise amplifier further includes a second neutralization circuit disposed between a drain and a source of the second field-effect transistor.

In some aspects, the techniques described herein relate to a radio-frequency module wherein the second neutralization circuit includes an adjustable capacitor.

In some aspects, the techniques described herein relate to a mobile device including: a transceiver configured to generate a radio-frequency signal; and a low-noise amplifier including an input node configured to receive the radio-frequency signal, an output node configured to output an amplified radio-frequency signal, a cascode amplifying stage configured to receive an operating power via a supply node and amplify the radio-frequency signal, the cascode amplifying stage including a first field-effect transistor with a gate coupled to the input node, and a second field-effect transistor disposed between the first field-effect transistor and the output node, and a feedback circuit connecting the supply node to the input node in order to increase an input impedance of the low-noise amplifier.

In some aspects, the techniques described herein relate to a mobile device wherein the feedback circuit includes a capacitor and a resistor connected in series.

In some aspects, the techniques described herein relate to a mobile device wherein the low-noise amplifier further includes a first neutralization circuit with one end connected to a cascode node between the first field-effect transistor and the second field-effect transistor.

In some aspects, the techniques described herein relate to a mobile device wherein the first neutralization circuit includes an adjustable capacitor.

In some aspects, the techniques described herein relate to a mobile device wherein another end of the first neutralization circuit is connected to a source of the first field-effect transistor.

In some aspects, the techniques described herein relate to a mobile device wherein another end of the first neutralization circuit is connected to a ground.

In some aspects, the techniques described herein relate to a mobile device wherein the low-noise amplifier further includes a second neutralization circuit disposed between a drain and a source of the second field-effect transistor.

In some aspects, the techniques described herein relate to a mobile device wherein the second neutralization circuit includes an adjustable capacitor.

In some aspects, the techniques described herein relate to a mobile device including: a transceiver configured to generate a radio-frequency signal; and a low-noise amplifier including an input node configured to receive the radio-frequency signal, an output node configured to output an amplified radio-frequency signal, a cascode amplifying stage configured to receive an operating power via a supply node and amplify the radio-frequency signal, the cascode amplifying stage including a first field-effect transistor with a gate coupled to the input node, and a second field-effect transistor disposed between the first field-effect transistor and the output node, and a first neutralization circuit with one end connected to a cascode node between the first field-effect transistor and the second field-effect transistor in order to increase an input impedance of the low-noise amplifier.

In some aspects, the techniques described herein relate to a mobile device wherein the first neutralization circuit includes an adjustable capacitor.

In some aspects, the techniques described herein relate to a mobile device wherein another end of the first neutralization circuit is connected to a source of the first field-effect transistor.

In some aspects, the techniques described herein relate to a mobile device wherein another end of the first neutralization circuit is connected to a ground.

In some aspects, the techniques described herein relate to a mobile device wherein the low-noise amplifier further includes a feedback circuit connecting the supply node to the input node.

In some aspects, the techniques described herein relate to a mobile device wherein the feedback circuit includes a capacitor and a resistor connected in series.

In some aspects, the techniques described herein relate to a mobile device wherein the low-noise amplifier further includes a second neutralization circuit disposed between a drain and a source of the second field-effect transistor.

In some aspects, the techniques described herein relate to a mobile device wherein the second neutralization circuit includes an adjustable capacitor.

### BRIEF DESCRIPTION OF THE DRAWINGS

FIG. 1 is a schematic diagram of one embodiment of a mobile device that can include any of the amplifiers described herein.

FIG. 2 is a schematic diagram of one embodiment of a transmit system for transmitting radio frequency (RF) signals from a mobile device.

FIG. 3A is a schematic diagram of a front-end system according to one embodiment that can include any of the amplifiers described herein.

FIG. 3B is a schematic diagram of a front-end system according to another embodiment that can include any of the amplifiers described herein.

FIG. 3C is a schematic diagram of an exemplary ultrahigh band (UHB) transmit and receive module.

FIG. 3D is a schematic diagram of an exemplary high band (HB) transmit and receive module.

FIG. 3E is a schematic diagram of an exemplary uplink carrier aggregation and MIMO module.

FIG. 4 illustrates an example of schematic diagram of a low noise amplifier (LNA) according to an embodiment of the present disclosure.

FIG. 5 illustrates an example of schematic diagram of an LNA according to an embodiment of the present disclosure.

FIG. 6 illustrates an example of schematic diagram of an LNA according to an embodiment of the present disclosure.

FIG. 7 illustrates an example of schematic diagram of an LNA according to an embodiment of the present disclosure.

FIG. 8 illustrates an example of schematic diagram of an LNA according to an embodiment of the present disclosure.

FIG. 9A is a schematic diagram of one embodiment of a packaged module that can include any of the amplifiers described herein.

FIG. 9B is a schematic diagram of a cross-section of the packaged module of FIG. 9A taken along the lines 9B-9B.

FIG. 10 is a schematic diagram of one embodiment of a phone board that can include the packaged module of FIGS. 9A-9B or any of the amplifiers described herein.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

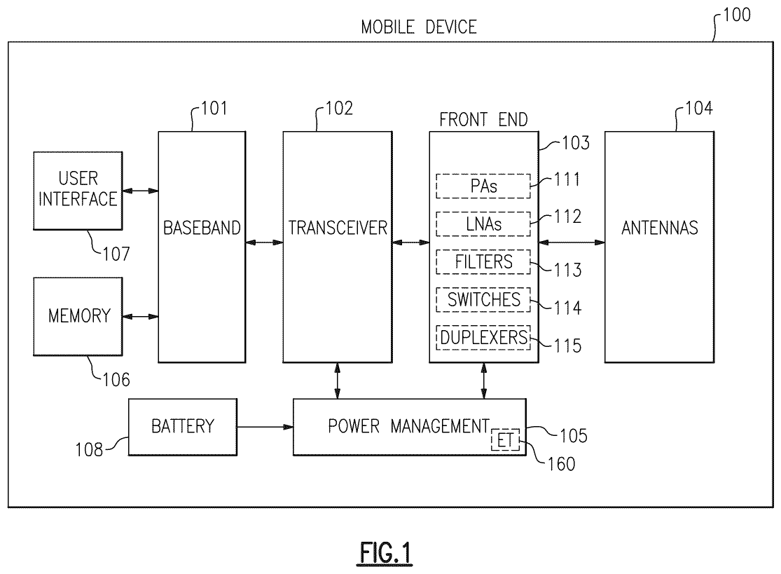

FIG. 1 is a schematic diagram of one example of a mobile device 100. The mobile device 100 includes a baseband system 101, a transceiver 102, a front end system 103, antennas 104, a power management system 105, a memory 106, a user interface 107, and a battery 108.

The mobile device 1000 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 102 generates RF signals for transmission and processes incoming RF signals received from the antennas 104. It will be understood that various functionalities associated with the transmission and receiving of RF signals can be achieved by one or more components that are collectively represented in FIG. 1 as the transceiver 102. In one example, separate components (for instance, separate circuits or dies) can be provided for handling certain types of RF signals.

The front end system 103 aids is conditioning signals transmitted to and/or received from the antennas 104. In the illustrated embodiment, the front end system 103 includes power amplifiers (PAs) 111, low noise amplifiers (LNAs) 112, filters 113, switches 114, and duplexers 115. Depending on the embodiment, the amplifiers in the front end system 103 (e.g., the LNAs 112) can include any of the amplifiers described herein. However, other implementations are possible.

For example, the front end system 103 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 100 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 104 can include antennas used for a wide variety of types of communications. For example, the antennas 104 can include antennas associated transmitting and/or receiving signals associated with a wide variety of frequencies and communications standards.

In certain implementations, the antennas 104 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 100 can operate with beamforming in certain implementations. For example, the front end system 103 can include phase shifters having variable phase controlled by the transceiver 102. Additionally, the phase shifters are controlled to provide beam formation and directivity for transmission and/or reception of signals using the antennas 104. For example, in the context of signal transmission, the phases of the transmit signals provided to the antennas 104 are controlled such that radiated signals from the antennas 104 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 104 from a particular direction. In certain implementations, the antennas 104 include one or more arrays of antenna elements to enhance beamforming.

The baseband system 101 is coupled to the user interface 107 to facilitate processing of various user input and output (I/O), such as voice and data. The baseband system 101 provides the transceiver 102 with digital representations of transmit signals, which the transceiver 102 processes to generate RF signals for transmission. The baseband system 101 also processes digital representations of received signals provided by the transceiver 102. As shown in FIG. 1, the baseband system 101 is coupled to the memory 106 of facilitate operation of the mobile device 100.

The memory 106 can be used for a wide variety of purposes, such as storing data and/or instructions to facilitate the operation of the mobile device 100 and/or to provide storage of user information.

The power management system 105 provides a number of power management functions of the mobile device 100. The power management system 105 of FIG. 1 includes an envelope tracker 160. As shown in FIG. 1, the power management system 105 receives a battery voltage form the battery 1008. The battery 108 can be any suitable battery for use in the mobile device 100, including, for example, a lithium-ion battery.

The mobile device 100 of FIG. 1 illustrates one example of an RF communication system that can include low noise amplifier(s) implemented in accordance with one or more features of the present disclosure. However, the teachings herein are applicable to RF communication systems implemented in a wide variety of ways.

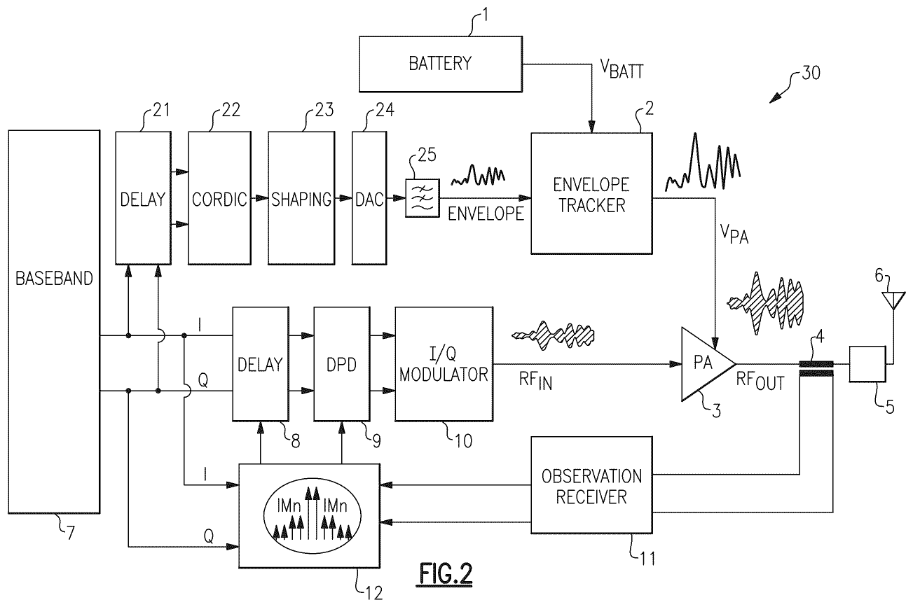

FIG. 2 is a schematic diagram of one embodiment of a transmit system for transmitting RF signals from a mobile device. The transmit system 30 includes a battery 1, an envelope tracker 2, a power amplifier 3, a directional coupler 4, a duplexing and switching circuit 5, an antenna 6, a baseband processor 7, a signal delay circuit 8, a digital pre-distortion (DPD) circuit 9, an I/Q modulator 10, an observation receiver 11, an intermodulation detection circuit 12, an envelope delay circuit 21, a coordinate rotation digital computation (CORDIC) circuit 22, a shaping circuit 23, a digital-to-analog converter 24, and a reconstruction filter 25.

The transmit system 30 of FIG. 2 illustrates one example of an RF communication system that can include power amplifier(s) implemented in accordance with one or more features of the present disclosure. However, the teachings herein are applicable to RF communication systems implemented in a wide variety of ways.

The baseband processor 7 operates to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals are provided to the I/Q modulator 10 in a digital format. The baseband processor 7 can be any suitable processor configured to process a baseband signal. For instance, the baseband processor 7 can include a digital signal processor, a microprocessor, a programmable core, or any combination thereof.

The signal delay circuit 8 provides adjustable delay to the I and Q signals to aid in controlling relative alignment between the envelope signal and the RF signal RF_{IN}. The amount of delay provided by the signal delay circuit 8 is controlled based on amount of intermodulation detected by the intermodulation detection circuit 12.

The DPD circuit 9 operates to provide digital shaping to the delayed I and Q signals from the signal delay circuit 8 to generate digitally pre-distorted I and Q signals. In the illustrated embodiment, the DPD provided by the DPD circuit 9 is controlled based on amount of intermodulation detected by the intermodulation detection circuit 12. The DPD circuit 9 serves to reduce a distortion of the power amplifier 3 and/or to increase the efficiency of the power amplifier 3.

The I/Q modulator 10 receives the digitally pre-distorted I and Q signals, which are processed to generate an RF signal RF_{IN}. For example, the I/Q modulator 10 can include DACs configured to convert the digitally pre-distorted I and Q signals into an analog format, mixers for upconverting the analog I and Q signals to radio frequency, and a signal combiner for combining the upconverted I and Q signals into an RF signal suitable for amplification by the power amplifier 3. In certain implementations, the I/Q modulator 10 can include one or more filters configured to filter frequency content of signals processed therein.

The envelope delay circuit 21 delays the I and Q signals from the baseband processor 7. Additionally, the CORDIC circuit 22 processes the delayed I and Q signals to generate a digital envelope signal representing an envelope of the RF signal RF_{IN}. Although FIG. 4 illustrates an implementation using the CORDIC circuit 22, an envelope signal can be obtained in other ways.

The shaping circuit 23 operates to shape the digital envelope signal to enhance the performance of the transmit system 30. In certain implementations, the shaping circuit 23 includes a shaping table that maps each level of the digital envelope signal to a corresponding shaped envelope signal level. Envelope shaping can aid in controlling linearity, distortion, and/or efficiency of the power amplifier 3.

In the illustrated embodiment, the shaped envelope signal is a digital signal that is converted by the DAC 24 to an analog envelope signal. Additionally, the analog envelope signal is filtered by the reconstruction filter 25 to generate an envelope signal suitable for use by the envelope tracker 2. In certain implementations, the reconstruction filter 25 includes a low pass filter.

With continuing reference to FIG. 2, the envelope tracker 2 receives the envelope signal from the reconstruction filter 25 and a battery voltage VBATT from the battery 1, and uses the envelope signal to generate a power amplifier supply voltage V_{PA} for the power amplifier 3 that changes in relation to the envelope of the RF signal RF_{IN}. The power amplifier 3 receives the RF signal RF_{IN} from the I/Q modulator 10, and provides an amplified RF signal RF_{OUT} to the antenna 6 through the duplexing and switching circuit 5, in this example.

The directional coupler 4 is positioned between the output of the power amplifier 3 and the input of the duplexing and switching circuit 5, thereby allowing a measurement of output power of the power amplifier 3 that does not include insertion loss of the duplexing and switching circuit 5. The sensed output signal from the directional coupler 4 is provided to the observation receiver 11, which can include mixers for down converting I and Q signal components of the sensed output signal, and DACs for generating I and Q observation signals from the downconverted signals.

The intermodulation detection circuit 12 determines an intermodulation product between the I and Q observation signals and the I and Q signals from the baseband processor 7. Additionally, the intermodulation detection circuit 12 controls the DPD provided by the DPD circuit 9 and/or a delay of the signal delay circuit 8 to control relative alignment between the envelope signal and the RF signal RF_{IN}.

By including a feedback path from the output of the power amplifier 3 and baseband, the I and Q signals can be dynamically adjusted to optimize the operation of the transmit system 30. For example, configuring the transmit system 30 in this manner can aid in providing power control, compensating for transmitter impairments, and/or in performing DPD.

Although illustrated as a single stage, the power amplifier 3 can include one or more stages. Furthermore, RF communication systems such as mobile devices can include multiple power amplifiers. In such implementations, separate envelope trackers can be provided for different power amplifiers and/or one or more shared envelope trackers can be used.

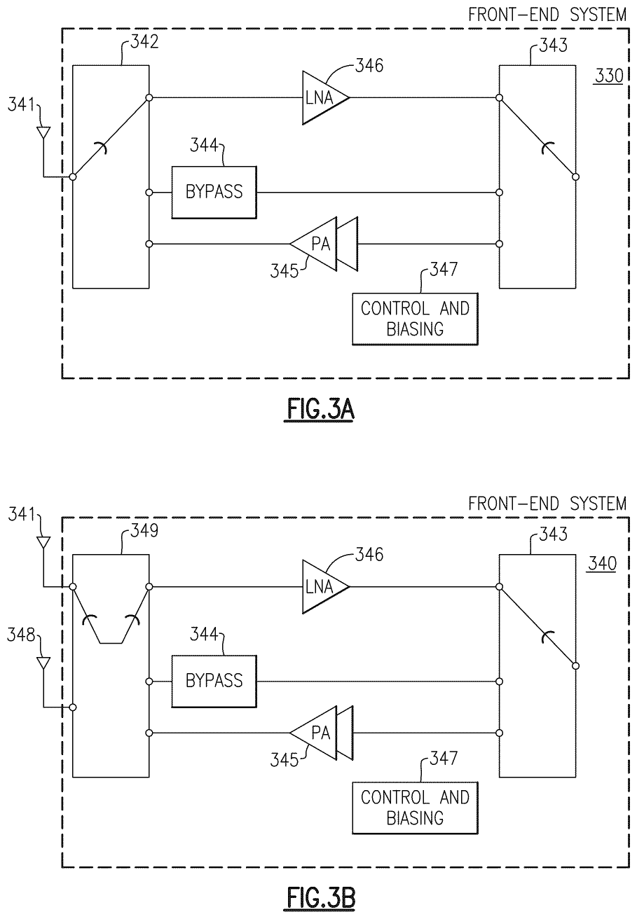

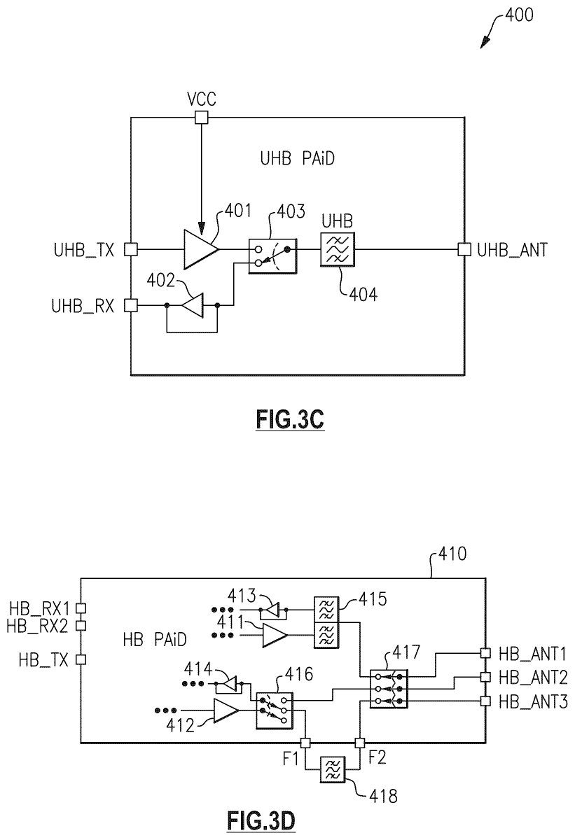

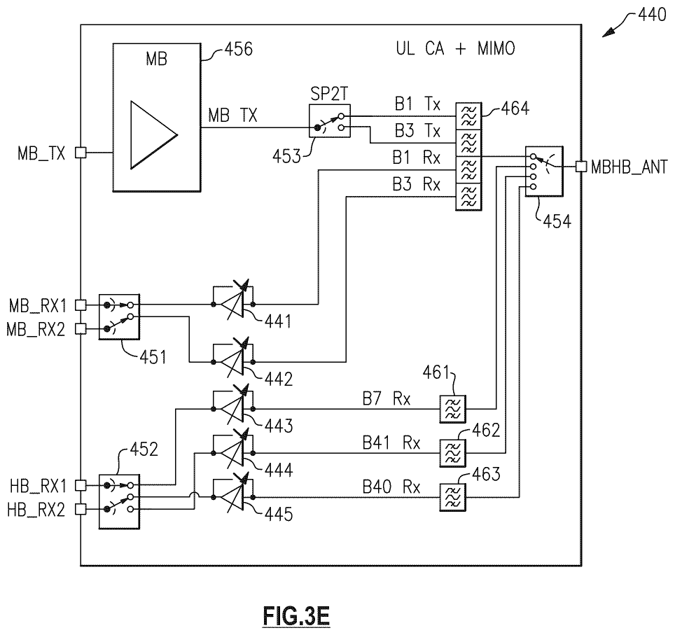

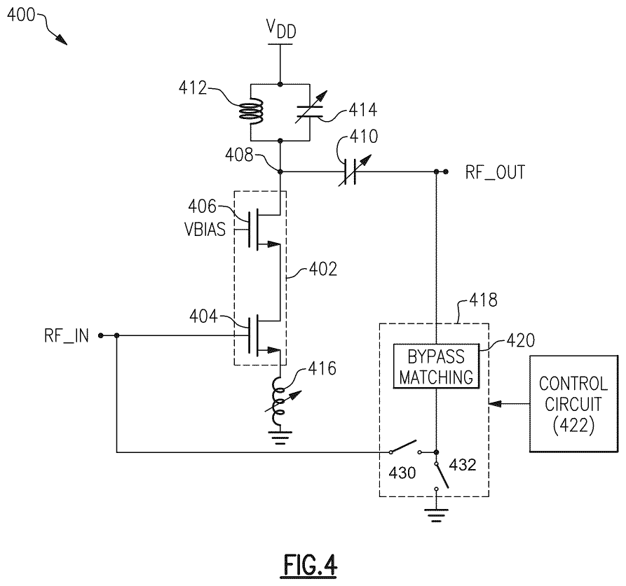

FIG. 3A is a schematic diagram of a front-end system 330 according to one embodiment.

The RF front-end system 330 is configured to receive RF signals from an antenna 341 and to transmit RF signals by way of the antenna 341. The illustrated front-end system 330 includes a first multi-throw switch 342, a second multi-throw switch 343, a receive signal path that includes an LNA 346, a bypass signal path that includes a bypass network 344, and a transmit signal path that includes a power amplifier 345.

The LNA 346 can be implemented in accordance with any of the principles and advantages discussed herein. The bypass network 344 can include any suitable network for matching and/or bypassing the receive signal path and the transmit signal path. The bypass network 344 can be implemented by a passive impedance network or by a conductive trace or wire. The power amplifier 345 can be implemented in a wide variety of ways.

The first multi-throw switch 342 can selectively connect a particular signal path to the antenna 341. The first multi-throw switch 342 can electrically connect the receive signal path to the antenna 341 in a first state, electrically connect the bypass signal path to the antenna 341 in a second state, and electrically connect the transmit signal path to the antenna 341 in a third state.

The second multi-throw switch 343 can selectively connect a particular signal path to an input/output port of the front-end system 330, in which the particular signal path is the same signal path electrically connected to the antenna 341 by way of the first multi-throw switch 342. Accordingly, the second multi-throw switch 343 together with the first multi-throw switch 342 can selectively connect a particular signal path between the antenna 341 and the input/output port of the front-end system 330.

The control and biasing circuit 347 can be used to control and bias circuitry of the RF front-end system 330, including, but not limited to, the LNA 346.

FIG. 3B is a schematic diagram of a front-end system 340 according to another embodiment.

The RF front-end system 340 of FIG. 3B is similar to the RF front-end system 330 of FIG. 3A, except that the first multi-throw switch 349 is configured to selectively connect a particular signal path to either a first antenna 341 or a second antenna 348. The multi-throw switch 649 can be a multi-throw, multi-pole switch.

The front-end systems of FIGS. 3A and 3B can be implemented in a packaged module. Such packaged modules can include relatively low cost laminate-based front-end modules that combine LNAs with power amplifiers and/or switch functions. Some such packaged modules can be multi-chip modules (MCMs).

In certain implementations, some or the all of the illustrated components in any of the front-end systems in FIGS. 3A and/or 3B can be embodied on a single integrated circuit or die. Such a die can be manufactured using any suitable process technology. According to some implementations, one or more antennas can be integrated with any of the front-end systems discussed herein.

FIG. 3C is a schematic diagram of a UHB transmit and receive module 400 (i.e., a front-end module) according to one example. The UHB transmit and receive module 400 operates to generate a UHB signal for transmission and to process a UHB signal received from an antenna.

The UHB transmit and receive module 400 illustrates one implementation of a UHB module suitable for incorporation in a RF system, such as that of the mobile device 300 of FIG. 3. Although the UHB transmit and receive module 400 illustrates one implementation of a UHB module, the teachings herein are applicable to RF electronics including modules implemented in a wide variety of ways. For example, while the illustrated example is an ultra-high band (UHB) module, other embodiments can transmit and receive over bands having different (e.g., low-band, mid-band, or high-band) frequencies. Accordingly, other implementations of modules are possible, such as modules with more or fewer pins, different pins, more or fewer components, and/or a different arrangement of components.

The UHB transmit and receive module 400 includes a power amplifier 401, a low noise amplifier 402, a transmit/receive switch 403, and a UHB filter 404, which is used to pass one or more UHB bands, for instance, Band 42, Band 43, and/or Band 48. As will be discussed herein, the power amplifier 401 or the low noise amplifier 402 can include a bypass path connecting an input of the amplifier to an output of the amplifier without signal amplification. It will be understood by those skilled in the art that the bypass path(s) can be selectively coupled to either terminal of the amplifiers by a toggle switch or other mechanism. The bypass path(s) can further include signal conditioning and filtering stages and/or an impedance matching circuit. The UHB transmit and receive module 400 further includes pins, including a UHB_TX pin for receiving a UHB transmit signal for transmission, a UHB_RX pin for outputting a UHB receive signal, a UHB_ANT pin for connecting to an antenna, and a VCC pin for receiving a supply voltage for powering at least the power amplifier 401. In certain implementations, the VCC pin receives a shared supply voltage from a power management circuit (for example, a PMU, not shown) shared by multiple modules.

The illustrated UHB transmit and receive module 400 provides both transmit and receive functionality for UHB signals. Thus, when four instantiations of the UHB transmit and receive module 400 are coupled directly or indirectly to four antennas, both 4×4 RX MIMO for UHB and 4×4 TX MIMO for UHB can be achieved. Additionally, the UHB transmit and receive modules can be used to support carrier aggregation for UL and/or DL using one or more UHB carrier frequencies.

FIG. 3D is a schematic diagram of a high-band (HB) transmit and receive module 410 according to one example.

The RF systems disclosed herein can include one or more implementations of the HB transmit and receive module 410. Although the HB transmit and receive module 410 illustrates one implementation of an HB module, the teachings herein are applicable to RF electronics including HB modules implemented in a wide variety of ways as well as to RF electronics implemented without HB modules. For example, while the illustrated example is an HB module, other embodiments can transmit and receive over bands having different (e.g., low-band, mid-band, or ultra high-band) frequencies.

The HB transmit and receive module 410 includes a first power amplifier 411 for FDD communications, a second power amplifier 412 for TDD communications, a first low noise amplifier 413 for FDD communications, a second low noise amplifier 414 for TDD communications, an FDD duplexer 415, a transmit/receive switch 416, a multi-throw switch 417, and a pair of bypass paths corresponding to the first and second low noise amplifiers 413, 414. An external TDD filter 418 is also included in this example. In another example, the TDD filter 418 is included within the module 410.

The HB transmit and receive module 410 further includes a variety of pins, including an HB_TX pin for receiving an HB transmit signal for transmission, an HB_RX1 pin for outputting a first HB receive signal, an HB_RX2 pin for outputting a second HB receive signal, an F1 pin for connecting to one terminal of the external TDD filter 418, and an F2 pin for connecting to another terminal of the external TDD filter 418. The module 410 further includes an HB_ANT1 pin, an HB_ANT2 pin, and an HB_ANT3 pin for connecting to one or more antennas.

FIG. 3E is a schematic diagram of an exemplary MIMO front-end module 440 supporting uplink carrier aggregation.

The MIMO module 400 can include one or more instantiations of a power amplifier module (PAM) as discussed herein. The MIMO module 400 can include an MB RX switch 451, an HB RX switch 452, a TX band switch 453, an MB/HB antenna switch 454, a plurality of RX amplifiers 441-445 (e.g., low-noise amplifiers), power amplifier circuitry 456, a plurality of HB RX filters 461-463, and one or more MB filters 464. The MIMO module 440 further includes a variety of pins, including an MB_TX pin for receiving an MB transmit signal for transmission, MB_RX1 and MB_RX2 pins for outputting received MB signals, and HB_RX1 and HB_RX2 for outputting received HB signals. The module 440 further includes an MB/HB_ANT pin for connecting to one or more antennas. While the illustrated example is an MB/HB module, other embodiments can transmit and receive over bands having different (e.g., low-band or ultra-high band) frequencies.

FIG. 4 illustrates an example of schematic diagram of a low-noise amplifier (LNA) 400. The LNA 400 shown in FIG. 4 may be a part of a front end system 103 of FIG. 1 or LNA 346 of FIGS. 3A-3B.

The LNA 400 may include an input node (RF_IN) configured to receive RF signal, and an out put node (RF_OUT) configured to output an amplified RF signal.

As shown in FIG. 4, the LNA 400 may also include a cascode amplifier 402 configured to receive an operating power via a supply node 408 and to amplify the RF signal using the operating power. The cascode amplifier 402 may include a first field-effect transistor (FET) 404 and a second FET 406. The second FET 406 may be disposed between the first FET 402 and the output node RF_OUT. The first FET 404 may have a gate coupled to input node RF_IN, a source coupled to a ground, and a drain coupled to the second FET 406. The source of the first FET 404 may be coupled to the ground via an inductor 416. The second FET 406 may have a gate configured to receive bias voltage VBIAS, a source coupled to the drain of the first FET 404, and a drain coupled to a supply node 408 which provides an operating power for the LNA 400.

The supply node 408 may be connected to supply source via a LC circuit including a capacitor 414 and an inductor 412 connected to each other in parallel. The supply node 408 may be connected to output node RF_OUT. A capacitor 410 may be disposed between the supply node 408 and the output node RF_OUT.

The LNA 400 may further include a bypass module 418. The bypass module 418 may include a bypass matching circuit 420 and several number of switches. In one example, the bypass circuit 420 may include a capacitor. In order to control the bypass module 418, the LNA 400 may further includes a control circuit 422. The control circuit 422 can control the switches 430 depending on the operating mode. For example, when amplifying the signal provided on RF_IN, the control circuit 422 can control switch 430 to be open, thereby disconnecting RF_IN from the bypass path, and can further bias the transistor 404 for amplifying RF_IN. When in bypass mode, the control circuit 422 can close the switch 430, thereby connecting RF_IN to the bypass path, and can deactivate/turn off the transistor 404.

Input Impedance, ZIN, is an important parameter in the design of a transistor amplifier and as such allows amplifiers to be characterized according to their effective input and output impedances as well as their power and current ratings. The input impedance of an amplifier is the input impedance “seen” by the source driving the input of the amplifier. If it is too low, it can have an adverse loading effect on the previous stage and possibly affecting the frequency response and output signal level of that stage.

In most applications, the amplifiers are directly or indirectly coupled to filters, and therefore it is very important for the amplifiers to be matched for the input/output impedance with coupled filters. For example, in case of mismatch, S11/gain will be spread over the frequencies and the contour size of the device will be bigger.

However, in most applications, the input impedance of LNA is lower than the output impedance of the filter. Therefore, in this disclosure, the LNAs with higher input impedance are introduced.

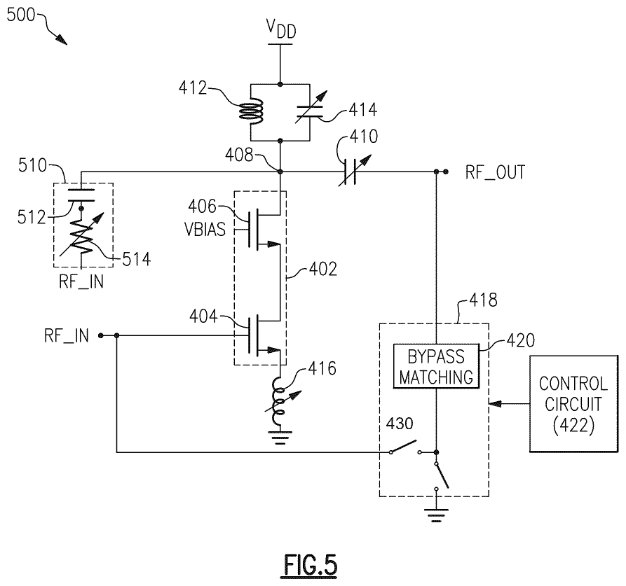

FIG. 5 illustrates an example of a schematic diagram of an LNA 500 according to an embodiment of the present disclosure. The LNA 500 shown in FIG. 5 is similar to the amplifier 400 shown in FIG. 4, except that the LNA 500 further includes a feedback circuit 510.

The feedback circuit 510 may be configured to increase the input impedance of the LNA 500 such to more optimally match with the output impedance of the filters.

According to an embodiment, the feedback circuit 510 may be disposed to connect the input node RF_IN and the supply node 408. The feedback circuit 510 may include a capacitor 512 and an adjustable resistor 514 connected to each other in series. More specifically, the capacitor 512 may be connected to the supply node 408, and the resistor 514 may be connected to the input node RF_IN. The resistance of the resistor 514 may be controlled by the control circuit 422.

According to this embodiment, the input impedance (Re_Zin) can be increased as can be found from Equation 1:

$$Re\_Zin \approx \frac{1 + gm \times RL}{{( w \times Cgs )}^{2} \times ( Rfb + {R}_{L} )} + \frac{gm \times Lm}{Cgs} \qquad [ Equation 1 ]$$

In Equation 1, gm is a transconductance equivalent of the first FET 404 and second FET 406, R_{L} is an impedance at the drain of the second FET 406, w is the frequency, Cgs is a capacitance between gate and source of the first FET 404, Rfb is a resistance of the resistor 514 in feedback circuit 510.

The first part of Equation 1 represents the effect of added Rfb, and the second part of Equation 1 represents induced degeneration value for the input impedance.

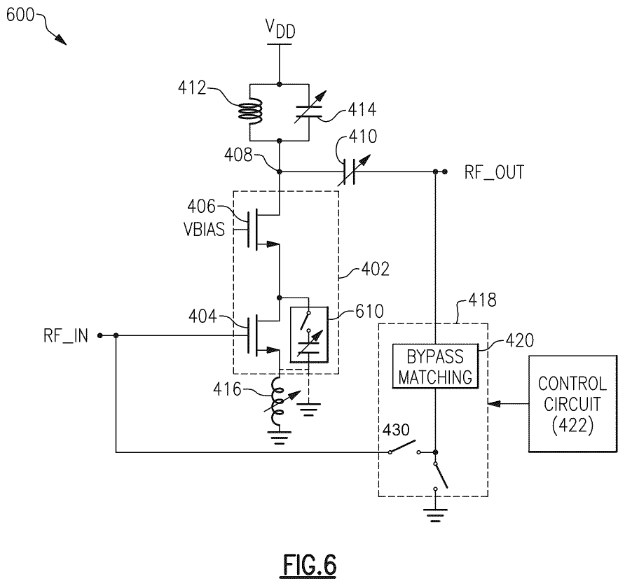

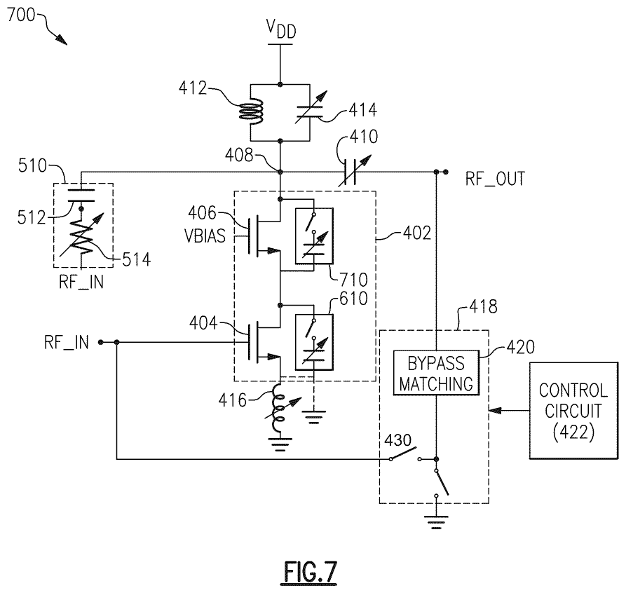

According to an embodiment, the LNA 500 may further includes a first neutralization circuit and/or a second neutralization circuit, as will de described in further details with FIGS. 6 and 7.

FIG. 6 illustrates an example of schematic diagram of an LNA 600 according to an embodiment of the present disclosure. The LNA 600 shown in FIG. 6 is similar to the amplifier 400 shown in FIG. 4, except that the LNA 600 further includes a first neutralization circuit 610. Neutralization is the process of counteracting or “neutralizing” the effects of interelectrode capacitance inside the amplifier.

According to this embodiment, the first neutralization circuit 610 may be configured to increase the input impedance of the LNA 600. The first neutralization circuit 600 may have one end connected to a cascode node between the first FET 404 and the second FET 406. The cascode node may be the connecting node of the first FET 404 and the second FET 406. Thus, the cascode node may be the drain of the first FET 404 and the source of the second FET 406.

The first neutralization circuit 610 may include an adjustable capacitor. The capacitance of the capacitor can be controlled by the control circuit 422. The other end of the first neutralization circuit 610 may be connected to the source of the first FET 404, as indicated by the horizontal dashed line between the capacitor and the source of the first FET 404. Alternatively, the other end of the first neutralization circuit 610 may be connected to the ground, as indicated by the vertical dashed line between the capacitor and ground.

According to this embodiment, the input impedance (Re_Zin) of the other end of the first neutralization circuit 610 connected to the source of the first FET 404 can be increased as can be found from Equation 2:

$$Re\_Zin \approx \frac{gm \times L}{C g s} \times \frac{1}{( 1 - {w}^{2} \times L \times {C}_{neut} )} \qquad [ Equation 2 ]$$

In Equation 2, gm is a transconductance equivalent of the first FET 404 and the second FET 406, L is a degeneration inductance of the first FET 404, w is the frequency, Cneut is a capacitance of the first neutralization circuit 610. The second part of Equation 2 represents the effect of neutralization achieved by the capacitance of the first neutralization circuit 610.

According to an embodiment, the LNA 600 may further include the feedback circuit 510 of FIG. 5, and/or a second neutralization circuit, as will de described in further detail with FIG. 7.

FIG. 7 illustrates an example of schematic diagram of LNA 700 according to an embodiment of the present disclosure. The LNA 700 shown in FIG. 7 is similar to the amplifier 400 shown in FIG. 4, except that the LNA 700 further includes the feedback circuit 510 and the first neutralization circuit 610. Furthermore, according to an embodiment, the LNA 700 may further include the second neutralization circuit 710. The feedback circuit 510 shown in FIG. 7 may be similar to that of FIG. 5, and the first neutralization circuit 610 of FIG. 7 may be similar to that of FIG. 6. According to this embodiment, the LNA 700 may include both feedback circuit 510 and the first neutralization circuit 610.

The second neutralization circuit 710 may be disposed between the drain and the source of the second FET 406. The second neutralization circuit 710 may include an adjustable capacitor. The capacitance of the capacitor in the second neutralization circuit 710 can be controlled by the control circuit 422.

According to embodiments of the present disclosure, it is possible to increase the input impedance while maintaining other performance parameters of the LNA. Thus, impedance matching with the filters can be accomplished without other losses.

FIG. 8 illustrates an example of schematic diagram of LNA 800 according to an embodiment of the present disclosure. In this embodiment, the LNA 800 may have a plurality of input nodes (IN1, IN2, IN3) each connected to a gate of a corresponding transistor 404-1, 404-2, 404-3 of the cascode amplifier 402. For example, the signal inputs can each correspond to a different receive signal band of a front-end module according to any of the previous figures, such as B1 RX, B3 RX, B7 RX, B41 RX, or B40 RX of the module 440 of FIG. 3E. For example, while receiving in a first RX frequency band on the input IN1, the control circuit 422 can control the transistor 404-1 to be biased to amplify the input signal provided on IN1, and control the transistors 404-2, 404-3 corresponding to inactive inputs to be deactivated/OFF. In some embodiments, the control circuit 422 can close the switches connected to the inactive inputs IN2, IN3, along with the switch between the bypass path and ground, thereby tying inactive inputs IN2, IN3 to ground while receiving on IN1. Similarly, while receiving in a second RX frequency band on input IN2, the control circuit 422 can control the transistor 404-2 to be biased to amplify the input signal provided on IN2, and control the transistors 404-1, 404-3 corresponding to inactive inputs to be deactivated/OFF. In some embodiments, the control circuit 422 can close the switches connected to the inactive inputs IN1, IN3, along with the switch between the bypass path and ground, thereby tying inactive inputs IN1, IN3 to ground while receiving on IN2.

With respect to the bypass path, 420, while the cascode amplifier 800 is in an amplifying mode, the control circuit 422 closes the switch connected between the bypass path and ground. In some such cases, the control circuit 422 additionally closes the switches connected between the inactive inputs (e.g., IN1, IN2, and/or IN3) and the bypass path, whereas leaving open at least the switch between the active input and the bypass path.

On the other hand, when the cascode amplifier 800 is in a bypass mode, the control circuit 422 leaves the switch connected between the bypass path and ground open, leaves the switches between the inactive inputs and the bypass open, and closes the switches from the active path to the bypass path and closes the switch positioned before the bypass matching module 418, thereby connecting the active input to RF_OUT and effectuating the bypass.

Although FIG. 8 shows three input nodes, the number of input nodes is not limited thereto.

Accordingly, the LNA 800 may have a plurality of first FETs 404-1, 404-2, 404-3. The drains of the first FETs are connected to each other, and the sources of the first FETs are connected to each other. The one end of the first neutralization circuit 610 may be connected to the drains of the first FETs. The other end of the first neutralization circuit 610 may be connected to either the ground or the sources of the first FETs.

The feedback circuit 510 may also have a plurality of resistors 514-1, 514-2, 514-3. Each of the resistors may be connected to respective input nodes. The number of input nodes corresponds to the number of first FETs and the resistors of feedback circuit 510. The resistors can be configured to adjust the input impedance of the amplifier 402 depending on which input is active. For example, if IN1 corresponding to a first receive band is currently active, the resistor 514-1 can be adjusted by the control circuit 422 to tune the input impedance, if IN2 corresponding to a second receive band is currently active, the resistor 514-2 can be adjusted to tune the input impedance, and if IN3 is currently active, the resistor 514-3 can be adjusted to tune the input impedance

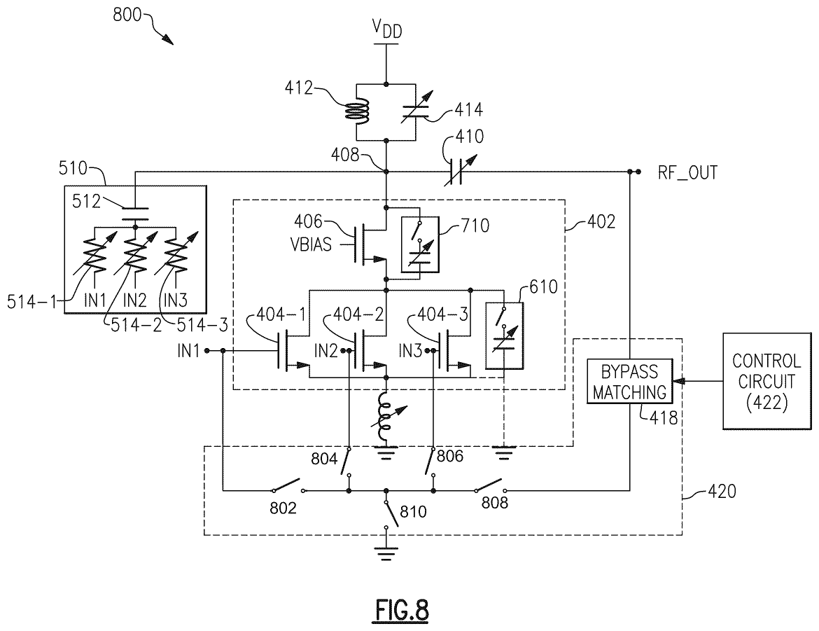

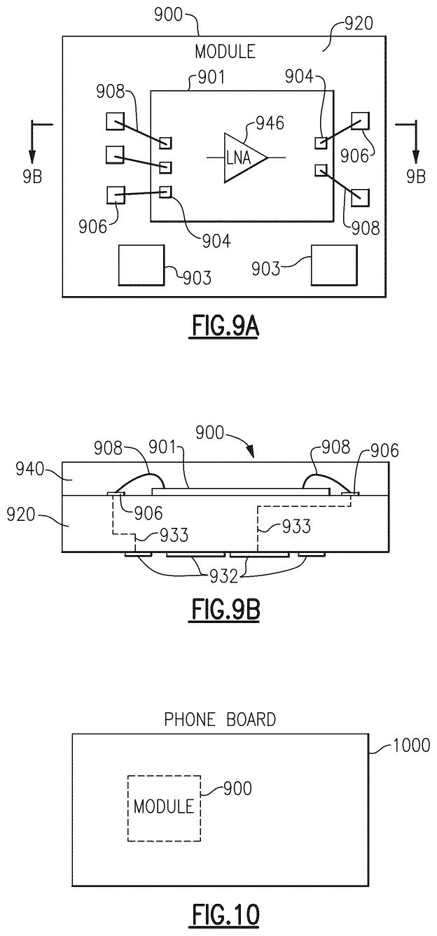

FIG. 9A is a schematic diagram of one embodiment of a packaged module 900. FIG. 9B is a schematic diagram of a cross-section of the packaged module 900 of FIG. 9A taken along the lines 9A-9B.

The packaged module 900 includes an IC or die 901, surface mount components 903, wirebonds 908, a package substrate 920, and encapsulation structure 940. The package substrate 920 includes pads 906 formed from conductors disposed therein. Additionally, the die 901 includes pads 904, and the wirebonds 908 have been used to electrically connect the pads 904 of the die 901 to the pads 906 of the package substrate 920.

The package module 900 includes a low noise amplifier 946, which can be implemented in accordance with any of the embodiments herein.

The packaging substrate 920 can be configured to receive a plurality of components such as the die 901 and the surface mount components 903, which can include, for example, surface mount capacitors and/or inductors.

As shown in FIG. 9B, the packaged module 900 is shown to include a plurality of contact pads 932 disposed on the side of the packaged module 900 opposite the side used to mount the die 901. Configuring the packaged module 900 in this manner can aid in connecting the packaged module 900 to a circuit board such as a phone board of a wireless device. The example contact pads 932 can be configured to provide RF signals, bias signals, power low voltage(s) and/or power high voltage(s) to the die 901 and/or the surface mount components 903. As shown in FIG. 9B, the electrically connections between the contact pads 932 and the die 901 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling of the packaged module 900. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

FIG. 10 is a schematic diagram of one embodiment of a phone board 1000. The phone board 1000 includes the module 900 shown in FIGS. 9A-9B attached thereto. Although not illustrated in FIG. 10 for clarity, the phone board 1000 can include additional components and structures.

### Applications

Some of the embodiments described above have provided examples in connection with wireless devices or mobile phones. However, the principles and advantages of the embodiments can be used for any other systems or apparatus that have needs for LNAs.

Such LNAs can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A radio frequency amplifier comprising:
a cascode amplifier configured to receive an operating power via a supply node and amplify a radio frequency signal, the cascode amplifier including a first field-effect transistor with a gate coupled to a first radio frequency input, and a second field-effect transistor disposed between the first field-effect transistor and a radio frequency output, a source of the second field-effect transistor connected to a drain of the first field-effect transistor;
a first neutralization circuit including a first tunable capacitor and connected at one end to a drain of the first field-effect transistor; and
a feedback circuit including a first tunable resistor and connected in series between the supply node and the first radio frequency input, the first tunable capacitor and the first tunable resistor controllable to increase an input impedance of the radio frequency amplifier.

2. The radio frequency amplifier of claim 1 further comprising a third field-effect transistor with a gate coupled to a second radio frequency input, and the source of the second field-effect transistor connected to a drain of the third field-effect transistor, and the feedback circuit further including a second tunable resistor connected in series between the supply node and the second radio frequency input.

3. The radio frequency amplifier of claim 2 wherein the first radio frequency input corresponds to a first receive frequency band and the second radio frequency input corresponds to a second receive frequency band.

4. The radio frequency amplifier of claim 1 further comprising a second neutralization circuit including a second tunable capacitor, the second neutralization circuit disposed between a drain and a source of the second field-effect transistor.

5. The radio frequency amplifier of claim 1 wherein the feedback circuit includes a capacitor and the first tunable resistor connected in series.

6. The radio frequency amplifier of claim 1 wherein another end of the first neutralization circuit is connected to a source of the first field-effect transistor.

7. The radio frequency amplifier of claim 1 wherein another end of the first neutralization circuit is connected to a ground.

8. A radio frequency module comprising:
a packaging substrate configured to receive a plurality of components; and
a radio frequency amplifier including a cascode amplifier configured to receive an operating power via a supply node and amplify a radio frequency signal, the cascode amplifier including a first field-effect transistor with a gate coupled to a first radio frequency input, and a second field-effect transistor disposed between the first field-effect transistor and a radio frequency output, a source of the second field-effect transistor connected to a drain of the first field-effect transistor; and a first neutralization circuit including a first tunable capacitor, the first neutralization circuit connected at one end to a drain of the first field-effect transistor; and a feedback circuit including a first tunable resistor and connected in series between the supply node and the first radio frequency input, the first tunable capacitor and the first tunable resistor controllable to increase an input impedance of the radio frequency amplifier.

9. The radio frequency module of claim 8 wherein the radio frequency module is a front-end module.

10. The radio frequency module of claim 8 wherein another end of the first neutralization circuit is connected to a source of the first field-effect transistor.

11. The radio frequency module of claim 8 wherein another end of the first neutralization circuit is connected to a ground.

12. The radio frequency module of claim 8 further comprising a second neutralization circuit including a second tunable capacitor, the second neutralization circuit disposed between a drain and a source of the second field-effect transistor.

13. The radio frequency module of claim 8 further comprising a third field-effect transistor with a gate coupled to a second radio frequency input, and the source of the second field-effect transistor connected to a drain of the third field-effect transistor, and the feedback circuit further including a second tunable resistor connected in series between the supply node and the second radio frequency input.

14. The radio frequency module of claim 13 wherein the first radio frequency input corresponds to a first receive frequency band and the second radio frequency input corresponds to a second receive frequency band.

15. A mobile device comprising:
a transceiver configured to generate a radio frequency signal; and
a radio frequency module including a cascode amplifier configured to receive an operating power via a supply node and amplify a radio frequency signal, the cascode amplifier including a first field-effect transistor with a gate coupled to a first radio frequency input, and a second field-effect transistor disposed between the first field-effect transistor and a radio frequency output, a source of the second field-effect transistor connected to a drain of the first field-effect transistor; and a first neutralization circuit including a first tunable capacitor, the first neutralization circuit connected at one end to a drain of the first field-effect transistor; and a feedback circuit including a first tunable resistor and connected in series between the supply node and the first radio frequency input, the first tunable capacitor and the first tunable resistor controllable to increase an input impedance of the cascode amplifier.

16. The mobile device of claim 15 wherein another end of the first neutralization circuit is connected to a source of the first field-effect transistor.

17. The mobile device of claim 15 wherein another end of the first neutralization circuit is connected to a ground.

18. The mobile device of claim 15 further comprising a second neutralization circuit including a second tunable capacitor, the second neutralization circuit disposed between a drain and a source of the second field-effect transistor.

19. The mobile device of claim 15 further comprising a third field-effect transistor with a gate coupled to a second radio frequency input, and the source of the second field-effect transistor connected to a drain of the third field-effect transistor, and the feedback circuit further including a second tunable resistor connected in series between the supply node and the second radio frequency input.

20. The mobile device of claim 19 wherein the first radio frequency input corresponds to a first receive frequency band and the second radio frequency input corresponds to a second receive frequency band.
